(19) United States
(12) Patent Application Publication
(10) Pub. No.: US 2021/0005765 A1
(43) Pub. Date: Jan. 7, 2021

(54) THIN FILM TYPE SOLAR CELL AND METHOD FOR MANUFACTURING THE SAME

(71) Applicants: Jun Ki MIN, Yongin-si (KR); Sang Su CHOI, Yongin-si (KR)

(72) Inventors: Jun Ki MIN, Yongin-si (KR); Sang Su CHOI, Yongin-si (KR)

(21) Appl. No.: 13/877,333

(22) PCT Filed: Sep. 21, 2011
(86) PCT No.: PCT/KR2011/006971

§ 371 Date: May 9, 2014

(30) Foreign Application Priority Data
Oct. 1, 2010 (KR) 10-2010-0095776

(51) Int. Cl. H01L 31/0465; H01L 31/0224; H01L 31/18

(52) U.S. Cl. CPC H01L 31/0465; H01L 31/1804; H01L 31/022433

(57) ABSTRACT

Disclosed is a thin film type solar cell with superior efficiency and a method for manufacturing the same.

The thin film type solar cell includes a substrate, one or more front electrodes arranged on the substrate such that the front electrodes are spaced from one another through a first trench, a semiconductor layer arranged on the front electrode, wherein a part of the semiconductor layer is removed by a second trench adjacent to the first trench, and one or more rear electrodes arranged on the second trench and the semiconductor layer such that the rear electrodes are spaced from one another through a third trench adjacent to the second trench, wherein the semiconductor layer include one or more connection members which are adjacent to the second trench and are divided by the second trench.

Based on such configuration, the thin film type solar cell and the method for manufacturing the same provide superior photoelectric transformation efficiency by connecting semiconductor layers arranged at both sides of the second trench through the connection member.

### TECHNICAL FIELD

The present invention relates to a thin film type solar cell with superior efficiency and a method for manufacturing the same.

### BACKGROUND ART

A solar cell is a device which converts light energy into electric energy using semiconductor characteristics.

The structure and principle of solar cell will be described in brief A solar cell has a PN junction structure in which a positive (p)-type semiconductor and a negative (n)-type semiconductor are junctioned.

When solar light is incident upon the solar cell having a structure, holes and electrons are generated in the semiconductor by the energy of incident solar light.

At this time, holes (+) and the electrons (−) move towards the p-type semiconductor and the n-type semiconductor, respectively, by an electric field generated at the PN junction, to produce electricity.

Such a solar cell may be classified into a substrate type solar cell and a thin film type solar cell.

The substrate type solar cell is manufactured using a semiconductor material such as silicon as a substrate and the thin film type solar cell is manufactured by forming a semiconductor in the form of a thin film on a substrate such as a glass.

The substrate type solar cell exhibits slightly superior efficiency, but has a limitation in minimizing a thickness during processes, and a disadvantage of increased manufacturing costs due to use of an expensive semiconductor substrate as a thin film type solar cell.

The thin film type solar cell exhibits slightly low efficiency, but advantageously enables slimness and reduces manufacturing costs, thus being suitable for mass-production, as compared to the substrate type solar cell.

The thin film type solar cell is manufactured by forming a front electrode on a substrate such as glass, forming a semiconductor layer on the front electrode and forming a rear electrode on the semiconductor layer.

Here, the front electrode forms a light-receiving face upon which light is incident and thus uses a transparent conductive material such as ZnO. As the area of the substrate increases, power loss is disadvantageously increased due to the resistance of transparent conductive material.

Accordingly, a method for minimizing power loss caused by resistance of the transparent conductive material in which the thin film type solar cell is divided into a plurality of unit cells and the plurality of unit cells are connected in series is developed.

Hereinafter, a method for manufacturing a conventional thin film type solar cell having a structure in which the plurality of unit cells are connected in series will be described with reference to the drawings.

FIGS. 1A to 1F are sectional views illustrating a method for manufacturing a conventional thin film type solar cell having a structure in which the plurality of unit cells are connected in series at respective steps.

Referring to FIG. 1A, a front electrode 20 is formed on a substrate 10 using a transparent conductive material such as ZnO.

Referring to FIG. 1B, in order to divide the front electrode 20 into a plurality of parts, the front electrode 20 is removed by a method such as a laser scribing process to form a first trench t1.

Referring to FIG. 1C, a semiconductor layer 30 is formed over the entire surface of the substrate 10 including the front electrode 20.

Referring to FIG. 1D, in order to divide the second electrode 30 into a plurality of parts, a predetermined region of the second electrode 30 is removed by a method such as laser scribing process to form a second trench t2.

Referring to FIG. 1E, a rear electrode 50 is formed on the semiconductor layer 30.

Referring to FIG. 1F, in order to divide the second electrode 30 into a plurality of parts, predetermined regions of the rear electrode 50 and the semiconductor layer 30 are removed by a method such as a laser scribing process to form a third trench t3.

Then, through the second trench t2 and the third trench t3, the semiconductor layer 30 is divided into two parts, that is, a first semiconductor layer 31 and a second semiconductor layer 32.

In addition, a plurality of rear electrode 50 is spaced from one another through the third trench t3 and is connected to the front electrode 20 through the second trench t2.

As such, the thin film type solar cell is divided into the plurality of unit cells through the third trench t3. In addition, the thin film type solar cell has a structure in which the front electrode 20 is connected to the rear electrode 50 through the second trench t2 and the plurality of unit cells are connected in series.

FIG. 2 is a perspective view illustrating the semiconductor layer divided through the second trench in FIG. 1F.

The semiconductor layer 30 absorbs solar light to produce electrons and holes. The electrons and holes are moved through an electrode to generate electricity.

In the solar cell, the maximum amount of electricity which can be generated on the substrate with a constant area is considerably important.

The semiconductor layer 30 directly receives solar light to produce electricity. As the volume of the semiconductor layer 30 in the unit cell increases, the amount of electricity generated increases.

### DISCLOSURE

### Technical Problem

However, the conventional thin film type solar cell has a disadvantage in which, since the semiconductor layer 30 is divided into the first semiconductor layer 31 and the second semiconductor layer 32 through the second trench t2, the second semiconductor layer 32 arranged in a right side of the second trench t2 does not greatly contribute to generation of electricity.

### Technical Solution

Accordingly, the present invention is directed to a thin film type solar cell and a method for manufacturing the same that substantially obviate one or more problems due to limitations and disadvantages of the related art.

It is one object of the present invention to provide a thin film type solar cell with superior photoelectric transformation efficiency and a method for manufacturing the same.

To achieve these objects and other advantages and in accordance with the purpose of the invention, as embodied and broadly described herein, provided is a thin film type solar cell including: a substrate; one or more front electrodes arranged on the substrate such that the front electrodes are spaced from one another through a first trench; a semiconductor layer arranged on the front electrode, wherein a part of the semiconductor layer is removed by a second trench adjacent to the first trench; and one or more rear electrodes arranged on the second trench and the semiconductor layer such that the rear electrodes are spaced from one another through a third trench adjacent to the second trench, wherein the semiconductor layer include a connection member which is adjacent to the second trench and connects parts divided by the second trench.

The thin film type solar cell may be divided into a plurality of unit cells through the third trench.

The parts of the semiconductor layer divided by the second trench may be spaced by a distance corresponding to the size of the second trench.

The connection member may be arranged such that the connection member crosses the side and inside of the second trench.

The semiconductor layer may include: a first semiconductor layer; and a second semiconductor layer separated from the second trench through the first semiconductor layer, wherein the first semiconductor layer is connected to the second semiconductor layer through the connection member.

The rear electrode may be filled in the second trench and the rear electrode may contact the front electrode through the second trench.

The extension of the second trench may be blocked by the connection member.

The second trench may have an extended groove which extends from one side of the semiconductor layer to the connection member arranged at the other side of the semiconductor layer.

The connection member may have the same thickness as the second trench.

The length of the connection member may be 1/10 or less of the length of the third trench.

The connection member may be present in plural in one unit cell. The connection member may be formed at both sides of the semiconductor layer in one unit cell.

The second trench may be surrounded by the first and second semiconductor layers, and the connection member.

The connection member may be spaced inward from both sides of the semiconductor layer by a distance in one unit cell and crosses the second trench to connect the first semiconductor layer to the second semiconductor layer.

The second trench may include a part which extends inside from one side of the semiconductor layer to the connection member and a part which extends inside from the other side of the semiconductor layer to the connection member.

The connection member may be arranged in the center of the second trench.

In accordance with another aspect of the present invention, provided is a method for manufacturing a thin film type solar cell including: forming a front electrode on a substrate; removing a predetermined region of the front electrode to form a first trench such that a plurality of divided parts of the front electrode are formed; forming a semiconductor layer on the front electrode; removing a part of the semiconductor layer to form a second trench adjacent to the first trench such that a plurality of divided parts of the semiconductor layer are formed; forming a rear electrode on the second trench and the semiconductor layer; and removing predetermined regions of the rear electrode and the semiconductor layer to form a third trench adjacent to the second trench such that a plurality of unit cells which are spaced from one another are formed, wherein the forming the second trench includes: forming a connection member which crosses the second trench and constitutes a part of the semiconductor layer, such that the connection member connects parts of the semiconductor layer divided by the second trench.

The forming the connection member may be carried out by forming the second trench such that the first semiconductor layer and the second semiconductor layer spaced by the second trench are connected to each other, while leaving a part of the semiconductor layer in a longitudinal direction in the unit cell.

The second trench may be formed by laser scribing.

The length of the connection member may be 1/10 or less of the length of the third trench.

The number of the connection member present in one unit cell may be at least one.

It is to be understood that both the foregoing general description and the following detailed description of the present invention are exemplary and explanatory and are intended to provide further explanation of the invention as claimed.

### Advantageous Effects

As apparent from the fore-going, the present invention provides a thin film type solar cell and a method for manufacturing the same in which semiconductor layers arranged at both sides of the second trench are connected to each other through the connection members to provide superior photoelectric transformation efficiency.

A plurality of conventionally separated semiconductor layers are connected to each other through the second trench, semiconductor layers which were almost not used can also perform photoelectric transformation, advantageously obtaining more electric energy.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

### DESCRIPTION OF DRAWINGS

The accompanying drawings, which are included to provide a further understanding of the invention and are incorporated in and constitute a part of this application, illustrate embodiment(s) of the invention and along with the description serve to explain the principle of the invention. In the drawings:

FIGS. 1A to 1F are sectional views illustrating a method for manufacturing a conventional thin film type solar cell having a structure in which the plurality of unit cells are connected in series, at respective steps;

FIG. 2 is a perspective view illustrating the semiconductor layer divided through the second trench in FIG. 1F;

FIG. 3 is a cross-sectional view illustrating a structure of a general solar cell;

FIGS. 4A to 4F are cross-sectional views illustrating a method for a thin film type solar cell according to one embodiment of the present invention, at respective steps;

FIG. 5 is a view illustrating connection members formed in the thin film type solar cell according to one embodiment of the present invention. FIG. 5A is a perspective view illustrating a semiconductor layer 130 divided by the second trench P2 in FIG. 4F, and FIG. 5B is a plan view illustrating a thin film type solar cell including connection members;

FIG. 6 is a view illustrating connection members formed in the semiconductor layer of the thin film type solar cell according to another embodiment of the present invention. FIG. 6(A) is a perspective view illustrating semiconductor layer divided by the second trench in FIG. 4F and FIG. 6(B) is a plan view illustrating a thin film type solar cell including the connection members; and

FIG. 7 is a view illustrating connection members formed in the semiconductor layer of the thin film type solar cell according to another embodiment of the present invention. FIG. 7(A) is a perspective view illustrating a semiconductor layer divided by the second trench in FIG. 4F and FIG. 7(B) is a plan view illustrating a thin film type solar cell including connection members.

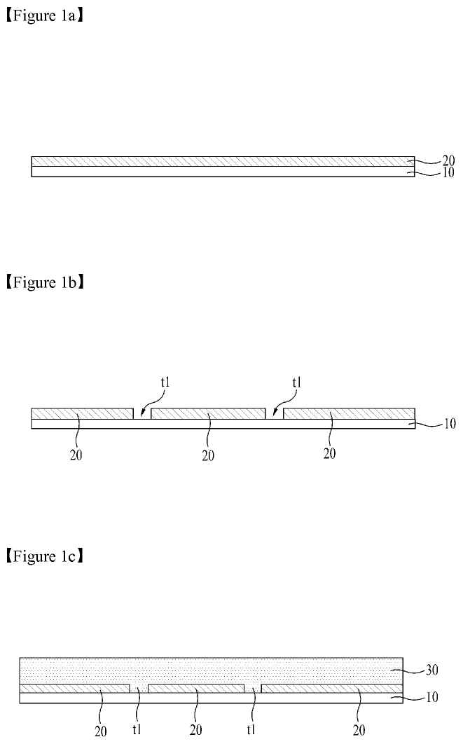

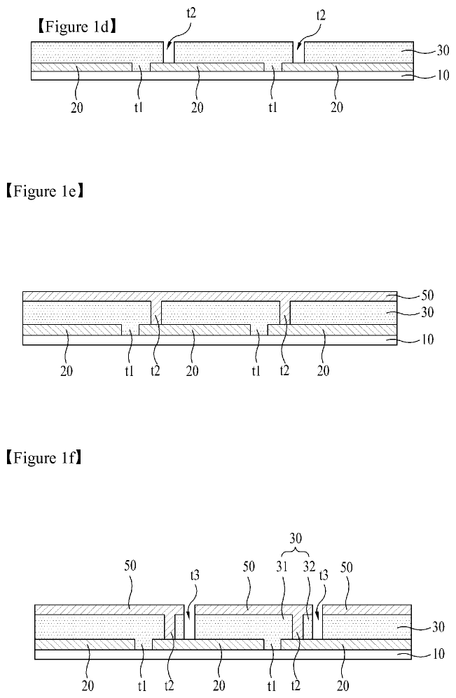

### MODE FOR INVENTION

Other aspects, features and advantages of the present invention will be more clearly understood from the following detailed description taken in conjunction with the accompanying drawings.

Hereinafter, the configurations and operations associated with preferred embodiments of the present invention will be described with reference to the annexed drawings in detail.

In the drawings, it should be noted that the same or similar elements are denoted by the same reference numerals even though they are depicted in different drawings.

FIG. 3 is a cross-sectional view briefly illustrating the structure of a general solar cell. The solar cell includes a semiconductor layer 1 having a PIN structure including a p-type semiconductor layer 2, a light-absorbing layer 3 and an n-type semiconductor layer 4, and a front electrode 5 and a rear electrode 6 are formed on an upper surface and a lower surface of the semiconductor layer 1, respectively.

An antireflective film may be formed on an upper surface of the front electrode 5.

In accordance with the principle of such solar cell, when light passes through the p-type semiconductor layer 2 and reaches the light-absorbing layer 3, electrons and holes are generated in the light-absorbing layer 3 through the photoelectric effect.

In addition, holes and electrons are incorporated in the p-type semiconductor layer 2 and the n-type semiconductor layer 4, respectively, through an inner electric field generated by the p-type semiconductor layer 2 and the n-type semiconductor layer 4.

Holes are accumulated in the p-type semiconductor layer 2, electrons are accumulated in the n-type semiconductor layer 4, and electric current is generated from the front electrode 1 and the rear electrode 5 connected to the p-type semiconductor layer 2 and the n-type semiconductor layer 4, respectively, to realize operation of a cell.

Here, the amounts of electrons and holes that can be accumulated in the solar cell when a predetermined amount of solar light is applied determine the efficiency of solar cell.

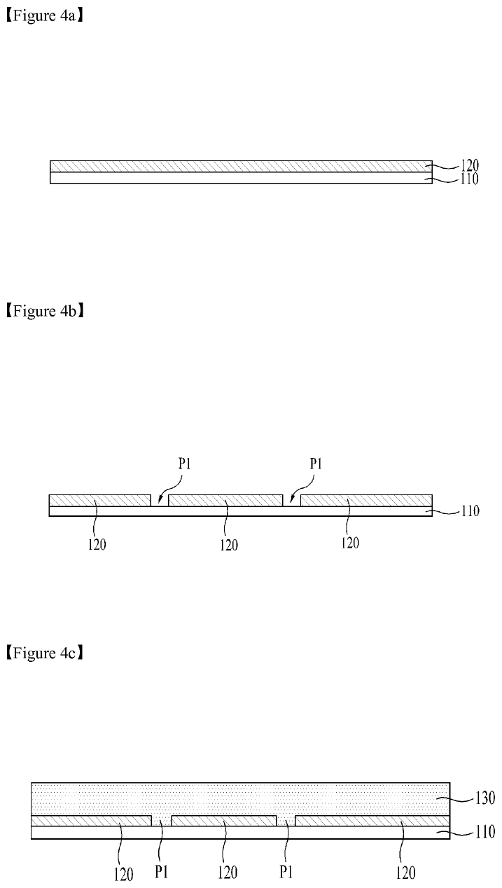

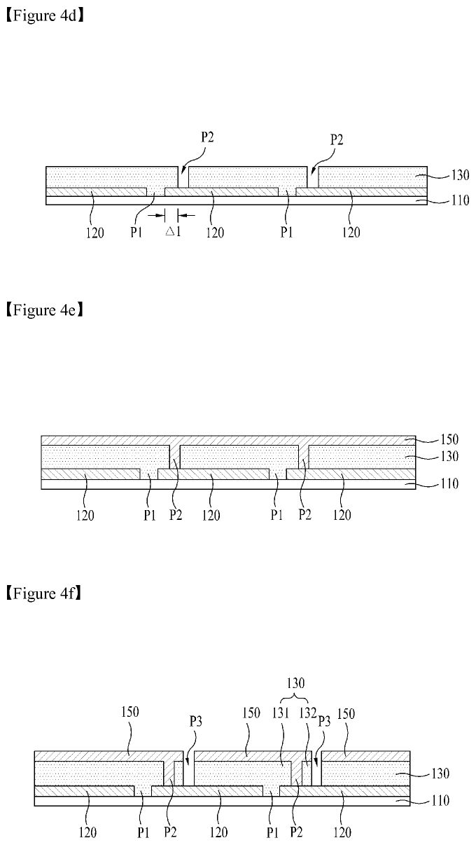

Hereinafter, a method for manufacturing a thin film type solar cell will be described with reference to FIGS. 4A to 4F.

FIGS. 4A to 4F are cross-sectional views illustrating a method for a thin film type solar cell according to one embodiment of the present invention, at respective steps.

Referring to FIG. 4A, a front electrode 120 is formed on a substrate 110 using a transparent conductive material (TCO) such as ZnO.

The substrate 110 serves as a body of the thin film type solar cell.

The substrate 110 is a part upon which light is primarily incident. Preferably, the substrate 220 is formed using a transparent conductive material so that it has superior light transmissivity and prevents short circuit in the thin film type solar cell.

For example, the material for the substrate 220 may be any one selected from soda-lime glasses, general glasses and reinforced glasses. In addition, the substrate 220 may be a substrate made of a polymer.

The front electrode 120 is made of a transparent conductive material to allow solar light incident through the substrate 110 to be incident upon the semiconductor layer 130 (see FIG. 4C).

Accordingly, the front electrode 120 is made of a transparent conductive material such as zinc oxide (ZnO), tin oxide (SnO2) or indium tin oxide (ITO).

The front electrode 120 is formed using a transparent conductive material by a chemical vapor deposition (CVD), a sputtering method or the like.

Referring to FIG. 4B, in order to divide the front electrode 120 into a plurality of parts, a predetermined region of the front electrode 120 is removed to form a first trench P1.

The formation of the first trench P1 may be carried out by an etching method using a photoresistor, a laser scribing method using laser beam or the like.

Of these methods, when the first trench P1 is formed using a laser scribing method, the necessity of using a mask or the like is eliminated, and the overall process of thin film type solar cell can be thus economically performed.

Referring to FIG. 4C, a semiconductor layer 130 is formed over the entire surface of the substrate 110 including the front electrode 120.

The semiconductor layer 130 may be made of any material which generates a photoelectromotive force when solar light is incident.

For example, the semiconductor layer 130 may be formed as a silicon-based, compound-based, organic-based or dry dye-sensitized solar cell.

The semiconductor layer 130 may have a single junction structure, a double junction structure or a multi (triple or more) junction structure.

The silicon-based solar cell may be one selected from single junction solar cells such as amorphous silicon (a-Si:H) or microcrystalline silicon (μc-Si:H) or amorphous silicon-germanium (a-SiGe:H), double junction solar cells such as an amorphous silicon/amorphous silicon (a-Si:H/a-Si:H), amorphous silicon/microcrystalline silicon (a-Si:H/μc-Si:H), amorphous silicon/polycrystalline silicon (a-Si:H/poly-Si), amorphous silicon/amorphous silicon germanium (a-Si:H/a-SiGe:H), and triple junction solar cells such as amorphous silicon/microcrystalline silicon/microcrystalline silicon (a-Si:H/μc-Si:H/μc-Si:H), amorphous silicon/amorphous silicon germanium/amorphous silicon germanium (a-Si:H/a-SiGe:H/a-SiGe:H), or amorphous silicon/amorphous silicon germanium/microcrystalline silicon(a-Si:H/a-SiGe:H/μc-Si:H).

The semiconductor layer 130 includes a first conductive type semiconductor layer, a photoelectric transformation layer, and a second conductive type semiconductor layer.

The first conductive type semiconductor layer may be a p-type layer or an n-type layer.

When the first conductive type semiconductor layer is a p- or n-type, the first conductive type semiconductor layer corresponding thereto may be an n- or p-type.

The first conductive type semiconductor layer, the photoelectric transformation layer, and the second conductive type semiconductor layer may be formed in accordance with a plasma enhanced chemical vapor deposition method in a chamber in which a reaction temperature is set at 400° C. or less.

The PECVD method may be a RF-PECVD method or a PECVD method using a high frequency power of a frequency of 150 MHz or less from a RF range to a VHF range.

Referring to FIG. 4D, in order to divide or separate the semiconductor layer 130 into a plurality of parts, a predetermined region of the semiconductor layer 130 is removed to form a second trench P2.

The second trench P2 is spaced from the first trench P1 by a predetermined distance (Δ1).

The distance (Δ1) between the first trench P1 and the second trench P2 prevents the first trench P1 from overlapping the second trench P2 after and before manufacturing of the thin film type solar cell is completed.

The formation of the second trench P2 may be carried out using an etching method using a photoresistor, or a laser scribing method using laser beam or the like.

The formation of the second trench P2 in the semiconductor layer 130 allows a part of the front electrode 120 arranged under the semiconductor layer 130 to be exposed through the second trench P2.

As such, two divided parts of the semiconductor layer 130 are formed such that the second trench P2 is interposed therebetween.

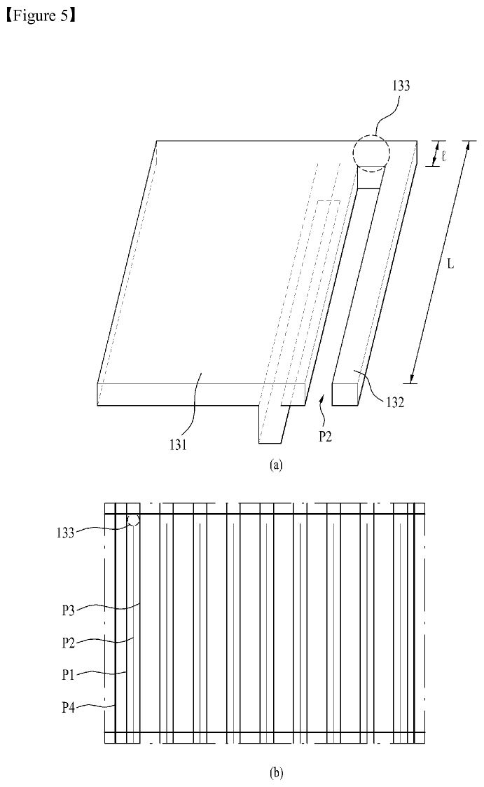

In this embodiment, the semiconductor layer 130 divided by the second trench P2 is provided with connection members 133, 233 and 333 (mentioned below) which cross the second trench P2 (see FIGS. 5 to 7).

In addition, parts of the semiconductor layer 130 divided by the second trench P2 may be connected to one another through the connection members.

The connection member will be described with reference to FIG. 5 below.

As shown in FIG. 4E, a rear electrode 150 is formed on the semiconductor layer 130.

The rear electrode 150 is made of a conductive light-reflecting material, since it serves as an electrode.

Accordingly, a material for the rear electrode 150 may be one of aluminum (Al), silver (Ag), gold (Au), copper (Cu), zinc (Zn), nickel (Ni) and chromium (Cr) and a combination thereof.

When the rear electrode 150 is formed, a conductive material is filled in the second trench P2 formed during the previous process.

When the rear electrode 150 filled in the second trench P2 contacts the front electrode 120, solar cells of adjacent unit cells are connected in series.

Referring to FIG. 4F, predetermined regions of the rear electrode 150 and the semiconductor layer 130 are removed to form a third trench P3.

As a result, a plurality of parts of the rear electrode 150 (referred to as “rear electrode parts”) which are spaced through the third trench P3 and connected through the second trench P2 to the front electrode 120 are formed.

The formation of third trench P3 may be carried out by an etching method using a photoresistor, a laser scribing method using laser beam or the like.

As a result, a thin film type solar cell having a plurality of unit cells is completed and integrated. One unit cell refers to a unit solar cell arranged in the center in FIG. 4F, which is divided by the third trench P3 arranged at both sides.

As a result of formation of the third trench P3, two semiconductor layers which are divided at both sides of the second trench P2, that is, a first semiconductor layer 131 and a second semiconductor layer 132 are arranged in one unit cell.

As mentioned above, the first semiconductor layer 131 and the second semiconductor layer 132 have connection members which cross the second trench P2 and they are connected to each other through the connection members.

Hereinafter, connection members formed in the semiconductor layer of the thin film type solar cell according to one embodiment will be described with reference to FIGS. 4D, 4E, 4F and 5.

FIG. 5 is a view illustrating connection members formed in the thin film type solar cell of the present invention. FIG. 5A is a perspective view illustrating a semiconductor layer 130 divided by the second trench P2 in FIG. 4F, and FIG. 5B is a plan view illustrating a thin film type solar cell including connection members.

Referring to FIGS. 4D and 4E, the second trench P2 allows a channel to connect the rear electrode 150 to the front electrode 120.

The second trench P2 may be formed by removing a predetermined region of the semiconductor layer 130 by laser scribing or the like.

Meanwhile, as mentioned above, the semiconductor layer 130 absorbs solar light to produce electrons and holes which move through the front electrode 120 and the rear electrode 150 to generate electricity.

The semiconductor layer 130 receives solar light and directly generates electricity. As the volume of the semiconductor layer 30 in the unit cell increases, the amount of electricity generated increases.

Accordingly, the second trench P2 allowing a channel to connect the rear electrode 150 to the front electrode 120 is formed, but the second trench P2 is formed by removing the semiconductor layer 130 in a longitudinal direction of the thin film type solar cell, and the amount of generated electricity thus decreases in the unit cell corresponding to the removed region of the semiconductor layer 130.

As shown in FIG. 5A, in the first embodiment of the present invention, a connection member 133 is formed in the unit cell such that the first semiconductor layer 131 and the second semiconductor layer 132 arranged at both sides of the second trench P2 are not entirely divided through the second trench P2.

That is, when the second trench P2 is formed by laser scribing, a part of the region provided between the first semiconductor layer 131 and the second semiconductor layer 132 is left to prevent complete separation of the first semiconductor layer 131 and the second semiconductor layer 132.

Although the region between the first semiconductor layer 131 and the second semiconductor layer 132 should be removed in order to form the second trench P2, laser scribing is preformed while excluding a part of the semiconductor layer 130 to form the connection member 133.

The connection member 133 is arranged at one side of the second trench P2 and extension of the second trench P2 is thus blocked by the connection member 133.

The second trench P2 has an extended groove which extends inward from the one side of the semiconductor layer 130, but the second trench P2 does not extend to the other side of the semiconductor layer 130.

That is, the connection member 133 is formed at the other side of the semiconductor layer 130 to connect the first semiconductor layer 131 to the second semiconductor layer 132.

The connection member 133 constitutes a part of the semiconductor layer 130 and is made of the same material as the semiconductor layer 130.

As shown in the drawing, the connection member 133 has the same thickness as the second trench P2. However, the thickness of the connection member 133 may be smaller than that of the second trench P2.

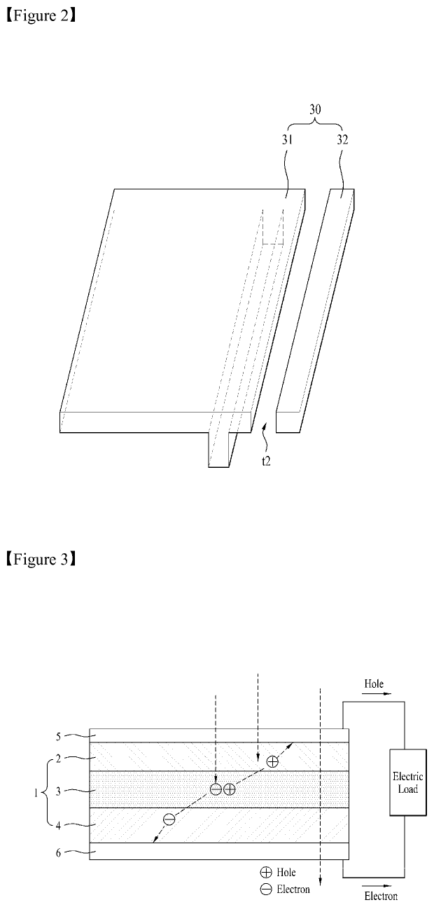

Accordingly, as compared to the case where the connection member 133 is not formed (see FIG. 2), the volume of semiconductor layer 130 increases in proportion to the region in which the connection member 133 is formed.

This causes an increase in the volume of the semiconductor layer 130 in the unit cell of solar cell and an increase in photoelectric transformation efficiency in proportion to the volume.

That is, when a predetermined amount of solar light is applied to a unit cell having a constant area, a greater amount of electricity can be generated therein.

In addition, as shown in FIG. 2, when the second trench t2 extends throughout the overall side of the semiconductor layer 30 from the one side to the other side in the unit cell, the semiconductor layer 30 is entirely divided into the first semiconductor layer 31 and the second semiconductor layer 32, the photoelectric transformation efficiency of the second semiconductor layer 32 arranged in the right side is considerably lower than that of the first semiconductor layer 31 arranged in the left side, and a dead zone where substantial photoelectric transformation performance is thus impossible is formed.

However, as shown in FIG. 5(A), the first semiconductor layer 131 is connected to the second semiconductor layer 132 through the connection member 133, thus maintaining the photoelectric transformation efficiency of the second semiconductor layer 132 to a level comparable to that of the first semiconductor layer 131.

Accordingly, as compared to the case where the connection member 133 is not present, the photoelectric transformation efficiency of solar cell can be increased.

Referring to FIG. 5(B), a first trench P1, a second trench P2 and a third trench P3 are sequentially formed on the thin film type solar cell.

The second trench P2 is adjacent to the first trench P1 and the third trench P3 is adjacent to the second trench P2.

As a result, a solar cell of one unit cell is formed and another unit cell is spaced from the third trench P3 in the one unit cell by a predetermined distance.

In the another unit cell, a first trench P1, a second trench P2 and a third trench P3 are formed in this order.

The thin film type solar cell has a structure in which a plurality of unit cells are integrated based on the fourth trench P4 having a substantial rectangle along the edge.

As shown in FIG. 5(B), the first trench P1 and the third trench P3 extend to the fourth trench P4, while the second trench P2 does not extend to the fourth trench P4.

As such, the connection member 133 is formed in an area in which formation of the second trench P2 is ceased. Such connection member 133 enables an increase in efficiency of the thin film type solar cell, as mentioned above.

The length or width of the connection member 133 should be determined within a suitable range so that the efficiency of the thin film type solar cell can be maximized.

As an experiment, the length or weight (l) of the connection member 133 is preferably 1/10 or less of the length or weight (L) of the third trench P3.

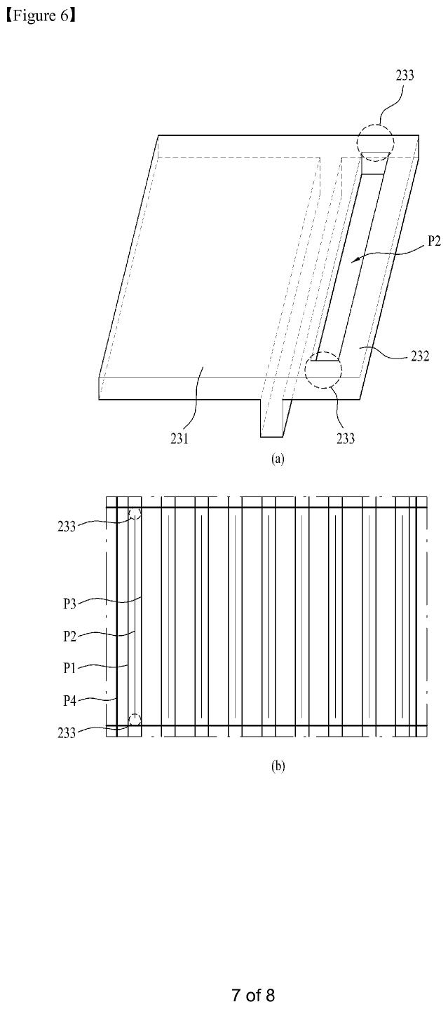

FIG. 6 is a view illustrating a connection member formed in the semiconductor layer of the thin film type solar cell according to another embodiment of the present invention. FIG. 6(A) is a perspective view illustrating a semiconductor layer divided by the second trench in FIG. 4F and FIG. 6(B) is a plan view illustrating a thin film type solar cell including the connection member.

The connection member 233 according to the embodiment may be present in plural in one unit cell.

In a second embodiment, the first semiconductor layer 231 is connected to the second semiconductor layer 232 through two connection members 233.

A plurality of connection members 233 are spaced from one another in one unit cell.

As shown in FIG. 6, the connection members 233 may be formed at both sides of the second trench P2, or may be spaced from one another such that they cross the second trench P2.

In this case, the total length of connection members 233 arranged at both ends is preferably maintained to 1/10 or less of the length of the third trench P3.

The second trench P2 is surrounded by the first and second semiconductor layers 231 and 232, and the connection member 233 and may have a groove shape in which upper and lower parts thereof open and four surfaces thereof close.

As shown in FIG. 6(B), the first trench P1 and the third trench P3 extend to the fourth trench P4, while the second trench P2 does not extend to the fourth trench P4.

Accordingly, the connection member 233 is formed between the fourth trench P4 and the second trench P2.

As such, the connection member 233 is formed in a region where the second trench P2 is not formed.

Such connection member 233 increases efficiency of the thin film type solar cell, as mentioned above.

The connection member 233 may be formed in three or more regions in one unit cell and the position at which connection members 233 are formed may be suitably selected.

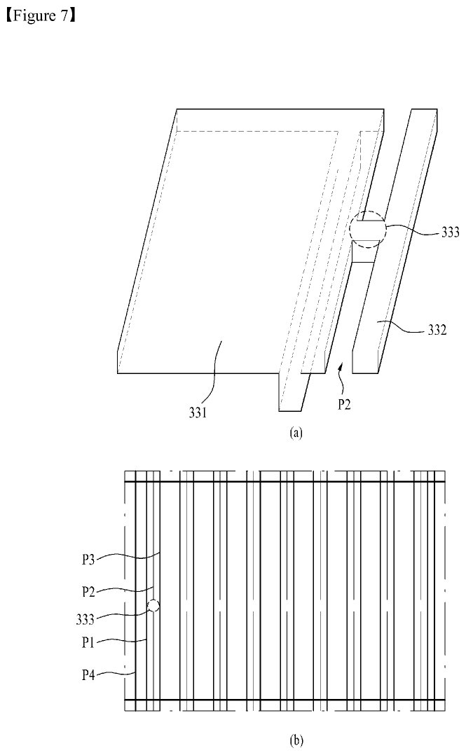

FIG. 7 is a view illustrating a connection member formed in the semiconductor layer of the thin film type solar cell according to yet another embodiment of the present invention. FIG. 7(A) is a perspective view illustrating semiconductor layer divided by the second trench in FIG. 4F and FIG. 7(B) is a plan view illustrating a thin film type solar cell including the connection member.

In this embodiment, the first semiconductor layer 331 is connected to the second semiconductor layer 332 through the connection member 333 arranged in the center of one unit cell. In this case, the length of the connection member 333 is preferably 1/10 or less of the length of the third trench P3.

The connection member 333 is arranged such that it is spaced inward from the both sides of the semiconductor layers 331 and 332 by a predetermined distance in one unit cell and crosses the second trench P2 to connect the first semiconductor layer 331 to the second semiconductor layer 332.

In addition, the second trench P2 may include a part which extends inward from one side of the semiconductor layers 331 and 332 to the connection member 333, and a part which extends inward from the other side of the semiconductor layers 331 and 332 to the connection members 333.

Meanwhile, the connection members 333 may be arranged in the center of the second trench P2.

Referring to FIG. 7(B), the both ends of the second trench P2 extend to the fourth trench P4, while the center of the second trench P2 is severed.

As such, the connection member 333 is formed in a region where the second trench P2 is not formed.

The connection members 333 enables an increase in efficiency of the thin film type solar cell as mentioned above.

As mentioned above, in the thin film type solar cells according to the preferred embodiments, the semiconductor layer spaced by the second trench P2 in a unit cell is entirely not divided by the second trench P2 and parts thereof are connected through connection members 133, 233 and 333 which cross the second trench P2.

The connection members 133, 233 and 333 are formed to connect adjacent first and second semiconductor layers 131 and 132; 231 and 232; and 331 and 332 by laser-scribing the semiconductor layer, while excluding a part thereof, when the second trench P2 is formed in a longitudinal direction of the thin film type solar cell by laser scribing.

The connection members 133, 233 and 333 may be formed in plural in one unit cell and the formation positions thereof are not limited.

The volume of the semiconductor layer increases in proportion to the volumes of connection members 133, 233 and 333 which cross the second trench P2, and the volume of the semiconductor layer increases and photoelectric transformation efficiency of the thin film type solar cell also increases in one unit cell, as compared to the case where the connection members 133, 233 and 333 are not formed.

Accordingly, a greater amount of electricity can be generated in a solar cell with a constant area.

In addition, since the first semiconductor layers 131, 231 and 331, and the second semiconductor layers 132, 232 and 332 arranged at both sides of the second trench P2 are connected to each other through connection members 133, 233 and 333, movement of holes and electrons produced by the semiconductor layers through the front electrode 120 and the rear electrode 150 can be facilitated, as compared to the case where the first semiconductor layer is separated from the second semiconductor layer.

Accordingly, photoelectric transformation efficiency can be further increased in the thin film type solar cell.

1. A thin film type solar cell comprising:
a substrate;
one or more front electrodes arranged on the substrate such that the front electrodes are spaced from one another through a first trench;
a semiconductor layer arranged on the front electrode, wherein a part of the semiconductor layer is removed by a second trench adjacent to the first trench; and
one or more rear electrodes arranged on the second trench and the semiconductor layer such that the rear electrodes are spaced from one another by a third trench adjacent to the second trench,
wherein the semiconductor layer includes a connection member which is adjacent to the second trench and connects parts being divided through the second trench.

2. The thin film type solar cell according to claim 1, wherein the thin film type solar cell is divided into a plurality of unit cells through the third trench.

3. The thin film type solar cell according to claim 2, wherein the parts of the semiconductor layer being divided by the second trench are spaced by a distance corresponding to the size of the second trench.

4. The thin film type solar cell according to claim 2, wherein the connection member is arranged such that the connection member crosses the side or inside of the second trench.

5. The thin film type solar cell according to claim 1, wherein the semiconductor layer includes:
a first semiconductor layer; and
a second semiconductor layer being separated from the second trench through the first semiconductor layer,
wherein the first semiconductor layer is connected to the second semiconductor layer by the connection member.

6. The thin film type solar cell according to claim 1, wherein the rear electrode is filled in the second trench and the rear electrode contacts the front electrode through the second trench.

7. The thin film type solar cell according to claim 1, wherein extension of the second trench is blocked by the connection member.

8. The thin film type solar cell according to claim 1, wherein the second trench is in shape of an extended groove which extends from one side of the semiconductor layer to the connection member arranged at the other side of the semiconductor layer.

9. The thin film type solar cell according to claim 7, wherein the connection member has the same thickness as the second trench.

10. The thin film type solar cell according to claim 1, wherein the length of the connection member is 1/10 or less of the length of the third trench.

11. The thin film type solar cell according to claim 1, wherein the connection member is present in plural in one unit cell.

12. The thin film type solar cell according to claim 5, wherein the connection member is formed at both sides of the semiconductor layer in one unit cell.

13. The thin film type solar cell according to claim 11, wherein the second trench is surrounded by the first and second semiconductor layers, and the connection member.

14. The thin film type solar cell according to claim 5, wherein the connection member is spaced inward from both sides of the semiconductor layer by a distance in one unit cell and crosses the second trench to connect the first semiconductor layer to the second semiconductor layer.

15. The thin film type solar cell according to claim 14, wherein the second trench includes a part which extends inside from one side of the semiconductor layer to the connection member and a part which extends inside from the other side of the semiconductor layer to the connection member.

16. A method for manufacturing a thin film type solar cell comprising:
forming a front electrode on a substrate;
removing a predetermined region of the front electrode to form a first trench such that a plurality of divided parts of the front electrode is formed;
forming a semiconductor layer on the front electrode;
removing a part of the semiconductor layer to form a second trench adjacent to the first trench such that a plurality of divided parts of the semiconductor layer are formed;
forming a rear electrode on the second trench and the semiconductor layer; and
removing predetermined regions of the rear electrode and the semiconductor layer to form a third trench adjacent to the second trench such that a plurality of unit cells spaced from one another are formed,
wherein the forming the second trench includes:
forming a connection member which crosses the second trench and constitutes a part of the semiconductor layer, such that the connection member connects parts of the semiconductor layer divided by the second trench.

17. The method according to claim 16, wherein the forming the connection member is carried out by forming the second trench such that the first semiconductor layer and the second semiconductor layer spaced by the second trench are connected to each other, while leaving a part of the semiconductor layer in a longitudinal direction in the unit cell.

18. The method according to claim 16, wherein the second trench is formed by laser scribing.

19. The method according to claim 16, wherein the length of the connection member is 1/10 or less of the length of the third trench.

20. The method according to claim 16, wherein the number of the connection member present in one unit cell is at least one.
